(19) United States
(12) Patent Application Publication
(10) Pub. No.: US 2026/0262294 A1
(43) Pub. Date: Sep. 3, 2026

(54) ARRAY BASE BOARD, DISPLAY PANEL AND DISPLAY DEVICE

(71) Applicants: Hefei Xinsheng Optoelectronics Technology Co., Ltd., Hefei, Anhui (CN); BOE Technology Group Co., Ltd., Beijing (CN)

(72) Inventors: Wei Feng, Beijing (CN); Shuangshuang Li, Beijing (CN)

(73) Assignees: Hefei Xinsheng Optoelectronics Technology Co., Ltd., Hefei, Anhui (CN); BOE Technology Group Co., Ltd., Beijing (CN)

(21) Appl. No.: 18/708,047

(22) PCT Filed: Aug. 28, 2023
(86) PCT No.: PCT/CN2023/115271

§ 371 Date: May 7, 2024

(51) Int. Cl. H10D 86/40

(52) U.S. Cl. CPC H10D 86/451; H10D 86/441

(57) ABSTRACT

An array base board is provided, wherein the array base board includes a substrate; the substrate is provided with a displaying region and a non-displaying region, the non-displaying region includes a lead-wire region and a trenching region, the trenching region is located at one side of the lead-wire region away from the displaying region, the trenching region includes a bonding region and a separating region, and the separating region is located between the bonding region and the lead-wire region; both of the lead-wire region and the trenching region include a lead-wire layer disposed on the substrate, the lead-wire region further includes plurality of types of protecting film layers that are arranged in layer configuration, and the plurality of types of protecting film layers are located at one side of the lead-wire layer away from the substrate; and at least two types of the protecting film layers within the lead-wire region extend to the separating region, and/or a dimension in a target direction of the separating region is greater than or equal to 20 μm, and less than or equal to 30 μm, wherein the target direction refers to a direction from the bonding region pointing to the lead-wire region.

### TECHNICAL FIELD

The present disclosure relates to the technical field of displaying and, more particularly, to an array base board, a display panel and a display device.

### BACKGROUND

With the development of the technique of displaying, various types of display devices emerge. However, no matter what type of display device usually includes an array base board, the array base board includes a displaying region and a non-displaying region, a plurality of pixel regions are arranged in an array within the displaying region, and each of the pixel regions includes a driving circuit for driving a pixel to emit light. Generally a scanning line and a data line are exported from the driving circuit, and the scanning lines and the data lines (hereinafter referred to as the lead wires) are wired in the array base board, and finally converge to the non-displaying region. The non-displaying region is provided with a bonding region, and within the bonding region those lead wires are connected to peripheral devices by using a packaging technique, for example, connected to a driving chip, thereby the operating states of the driving circuits within the displaying region are controlled based on the outputted signals of the driving chip to realize the display controlling.

In the related art, when the peripheral devices and the lead wires are connected within the bonding region by using a packaging process, firstly the surface of the non-displaying region is washed. However, during the washing, the lead wires within the non-displaying region are easily damaged, which results in the problem of the display panel of vertical-line imperfect and square-grid imperfect.

### SUMMARY

An array base board is provided by a first aspect of the present disclosure, wherein the array base board includes a substrate;
the substrate is provided with a displaying region and a non-displaying region, the non-displaying region includes a lead-wire region and a trenching region, the trenching region is located at one side of the lead-wire region away from the displaying region, the trenching region includes a bonding region and a separating region, and the separating region is located between the bonding region and the lead-wire region;
both of the lead-wire region and the trenching region include a lead-wire layer disposed on the substrate, the lead-wire region further includes a plurality of types of protecting film layers that are arranged in layer configuration, and the plurality of types of protecting film layers are located at one side of the lead-wire layer away from the substrate; and
at least two types of the protecting film layers within the lead-wire region extend to the separating region, and/or a dimension in a target direction of the separating region is greater than or equal to 20 μm, and less than or equal to 30 μm, wherein the target direction refers to a direction from the bonding region pointing to the lead-wire region.

As an example, the dimension in the target direction of the separating region increases with increasing of a quantity of the protecting film layers extending to the separating region.

As an example, when at least three instances of the types of the protecting film layers extend to the separating region, the dimension in the target direction of the separating region is greater than or equal to 200 μm, and less than or equal to 250 μm; and when two types of the protecting film layers extend to the separating region, the dimension in the target direction of the separating region is greater than or equal to 20 μm, and less than or equal to 30 μm.

As an example, the plurality of types of protecting film layers include:
a first passivating layer located at one side of the lead-wire layer away from the substrate;
an organic film layer located at one side of the first passivating layer away from the substrate;
a second passivating layer located at one side of the organic film layer away from the substrate; and
a first thin-film layer located at one side of the second passivating layer away from the substrate; and
the second passivating layer and the first thin-film layer extend to the separating region, the second passivating layer covers the separating region, and there is a gap between the first thin-film layer and the bonding region.

As an example, the first passivating layer further extends to the separating region, and the first passivating layer covers the separating region.

As an example, the dimension in the target direction of the separating region is greater than or equal to 20 μm, and less than or equal to 30 μm.

As an example, a spacing between the bonding region and the first thin-film layer is greater than or equal to 10 μm, and less than or equal to 20 μm.

As an example, the plurality of types of protecting film layers further include a second thin-film layer, the second thin-film layer is located at one side of the organic film layer away from the substrate, and the second passivating layer is located at one side of the second thin-film layer away from the substrate;
wherein the second thin-film layer extends to the separating region, and there is a gap between the second thin-film layer and the bonding region.

As an example, the first passivating layer further extends to the separating region, and the first passivating layer covers the separating region.

As an example, the dimension in the target direction of the separating region is greater than or equal to 20 μm, and less than or equal to 30 μm.

As an example, a spacing between the second thin-film layer and the bonding region is greater than or equal to 10 μm, and less than or equal to 20 μm; and a spacing between the first thin-film layer and the bonding region is greater than or equal to 10 μm, and less than or equal to 20 μm.

As an example, a spacing between the first thin-film layer and the bonding region is less than a spacing between the second thin-film layer and the bonding region.

As an example, the displaying region includes a plurality of pixel units arranged in an array, and each of the pixel units includes a pixel electrode, a common electrode and a thin-film transistor;
the pixel electrode is electrically connected to a source-drain electrode of the thin-film transistor, and the common electrode is further from the substrate than the pixel electrode is; and
the first thin-film layer and the common electrode are arranged in a same layer, and the second thin-film layer and the pixel electrode are arranged in a same layer.

As an example, the displaying region includes a plurality of pixel units arranged in an array, and each of the pixel units includes a pixel electrode, a common electrode and a thin-film transistor;
the pixel electrode is electrically connected to a source-drain electrode of the thin-film transistor, and the common electrode is closer to the substrate than the pixel electrode is; and
the first thin-film layer and the pixel electrode are arranged in a same layer, and the second thin-film layer and the common electrode are arranged in a same layer.

As an example, a thickness of the first passivating layer is greater than a thickness of the first thin-film layer, and/or a thickness of the second passivating layer is greater than a thickness of the first thin-film layer.

In the second aspect, a display panel is further provided, wherein the display panel includes the array base board, and a cell-assembling base board arranged in align with the array base board, and a liquid-crystal layer is filled between the cell-assembling base board and the array base board.

As an example, there is a gap between the bonding region of the array base board and an orthographic projection of the cell-assembling base board on the array base board, and a spacing of the gap is greater than or equal to 10 μm, and less than or equal to 20 μm.

In the third aspect, a display device is further provided, wherein the display device includes a controlling chip, and the display panel; and
the array base board of the display panel includes the bonding region, the bonding region includes exported electrodes lap-joined to the lead-wire layer, and the leads of the controlling chip are lap-joined to the exported electrodes.

As an example, the array base board of the display device includes the trenching region and the lead-wire region, and further includes:

a conducting thin film, wherein an orthographic projection of the conducting thin film on the substrate covers a part or a whole of an orthographic projection of the trenching region on the substrate.

As an example, the trenching region includes the separating region adjacent to the lead-wire region, and the bonding region adjacent to the separating region, and the dimension in the target direction of the separating region is greater than or equal to 20 μm, and less than or equal to 30 μm; and a dimension in the target direction of the conducting thin film is greater than or equal to 70 μm, and less than or equal to 110 μm;
wherein the target direction refers to the direction from the bonding region pointing to the lead-wire region.

The present disclosure provides an array base board, wherein the array base board includes a substrate; the substrate is provided with a displaying region and a non-displaying region, the non-displaying region includes a lead-wire region and a trenching region, the trenching region is located at one side of the lead-wire region away from the displaying region, the trenching region includes a bonding region and a separating region, and the separating region is located between the bonding region and the lead-wire region; both of the lead-wire region and the trenching region include a lead-wire layer disposed on the substrate, the lead-wire region further includes a plurality of types of protecting film layers that are arranged in layer configuration, and the plurality of types of protecting film layers are located at one side of the lead-wire layer away from the substrate; and at least two types of the protecting film layers within the lead-wire region extend to the separating region, and/or a dimension in a target direction of the separating region is greater than or equal to 20 μm, and less than or equal to 30 μm, wherein the target direction refers to a direction from the bonding region pointing to the lead-wire region.

In the array base board according to the present disclosure, the separating region is adjacent to the bonding region. Because two types of the protecting film layers are over the lead-wire layer within the separating region, when the surface of the non-displaying region is being washed, the lead-wire layer within the separating region can be protected by using the at least two types of the protecting film layers, to prevent water vapor from entering the lead-wire layer and corroding the lead wires. When the dimension of the separating region in the direction from the bonding region pointing to lead-wire region is greater than or equal to 20 μm, and less than or equal to 30 μm, the area of the separating region can be very low. In this way, the risk region where the lead-wire region is corroded within the separating region is highly reduced, therefore the risk in the lead-wire layer being corroded and cracking can be reduced. When the size of the separating region is reduced to below 30 μm and the separating region has at least two types of the protecting film layers, the lead-wire layer within the separating region is protected more effectively, thereby the risk in cracking of the lead wires during the packaging process and the reliability process is highly reduced, the problem of square-grid imperfect and vertical-line imperfect when the display panel is tested can be prevented.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly described below. Apparently, the figures that are described below are embodiments of the present disclosure, and a person skilled in the art can obtain other figures according to these figures without paying creative work. It should be noted that the scales in the drawings are merely illustrative and do not indicate the actual scales.

FIG. 1 shows a top view of the wiring within the non-displaying region of an array base board in the related art;

FIG. 2 shows a sectional view along a direction of AA′ of the non-displaying region in FIG. 1;

FIG. 3 shows a diagram of the area of the positions where the lead wires within the non-displaying region are damaged under a microscope;

FIG. 4 shows a schematic top planar view of an array base board according to an embodiment of the present disclosure;

FIG. 5 shows a schematic top planar view of an array base board according to an embodiment of the present disclosure within the trenching region;

FIG. 6 shows a sectional view along the direction of AA′ within the non-displaying region of an array base board according to an embodiment of the present disclosure;

FIG. 7 shows a schematic sectional structural diagram along the direction of AA′ of an array base board according to an embodiment of the present disclosure;

FIG. 8 shows an array base board according to an embodiment of the present disclosure in which the separating region includes three types of the protecting film layers;

FIG. 9 shows a sectional view along the direction of AA′ of an array base board according to an embodiment of the present disclosure when the separating region includes two types of the protecting film layers;

FIG. 10 shows a schematic sectional structural diagram of the displaying region of an array base board A according to an embodiment of the present disclosure;

FIG. 11 shows a schematic sectional structural diagram along the direction of AA′ of an array base board A according to an embodiment of the present disclosure;

FIG. 12 shows a schematic sectional structural diagram along the direction of AA′ of another array base board A according to an embodiment of the present disclosure;

FIG. 13 shows a schematic sectional structural diagram of the displaying region of another array base board B according to an embodiment of the present disclosure;

FIG. 14 shows a schematic sectional structural diagram along the direction of AA′ of an array base board B according to an embodiment of the present disclosure;

FIG. 15 shows a schematic sectional structural diagram along the direction of AA′ of another array base board B according to an embodiment of the present disclosure;

FIG. 16 shows a schematic sectional structural diagram of a display panel according to an embodiment of the present disclosure;

FIG. 17 shows a schematic sectional structural diagram of the displaying region of another array base board A according to an embodiment of the present disclosure;

FIG. 18a shows a schematic top planar view of the non-displaying region of a display device according to an embodiment of the present disclosure;

FIG. 18b shows a schematic top planar view of the non-displaying region of another display device according to an embodiment of the present disclosure;

FIG. 19a is a schematic sectional structural diagram along the direction of AA′ of the display device shown in FIG. 18a; and

FIG. 19b is a schematic sectional structural diagram along the direction of AA′ of the display device shown in FIG. 18b.

### REFERENCE NUMBERS

100: array base board; 101: displaying region; 102: non-displaying region; 1021: lead-wire region; 1022: trenching region; 221: separating region; 222: bonding region; 103: gate line; 104: data line; 11: substrate; 12: lead-wire layer; 13: protecting film layers; 14: gate insulating layer; 15: conducting thin film; 131: first passivating layer; 132: organic film layer; 133: pixel electrode; 134: second passivating layer; 135: common electrode; 122: gate; 122a: drain; 122b: source; 122c: active layer; 2211: exported electrode; 2212: via hole; 130a: first thin-film layer; 130b: second thin-film layer; 100A: array base board A; 100B: array base board B; 200: cell-assembling base board; 300: liquid-crystal layer; 400: controlling chip; h1: the dimension in the target direction of the separating region; h2: the spacing between the first thin-film layer and the bonding region; and h3: the dimension in the target direction of the conducting thin film starting from the bonding region.

### DETAILED DESCRIPTION

In order to make the objects, the technical solutions and the advantages of the embodiments of the present disclosure clearer, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

As mentioned in the BACKGROUND, when the peripheral devices and the lead wires are connected by using a packaging process, firstly the surface of the non-displaying region is washed. During the washing, the lead wires within the non-displaying region are easily damaged, which results in vertical-line imperfect and square-grid imperfect of the display panel. Specifically, by taking a thin film transistor liquid crystal display (referred to for short as a TFT-LCD) as an example, the problem in the related art will be described:

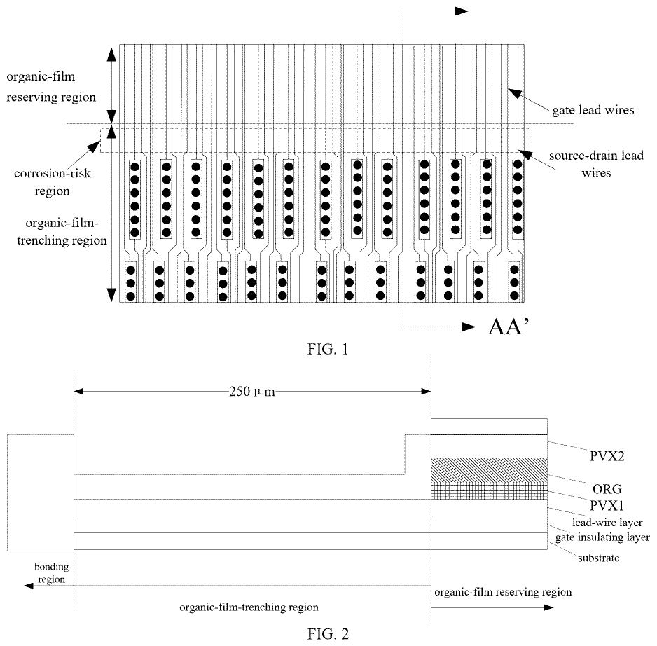

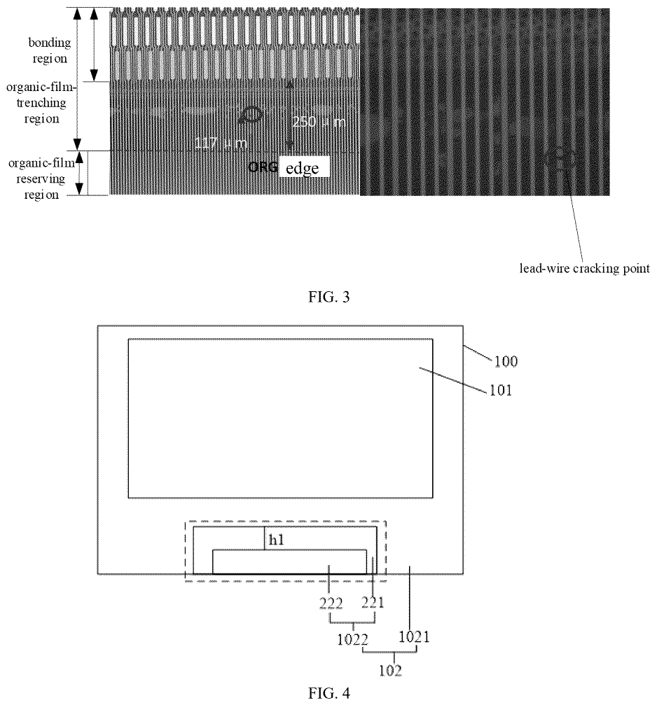

Referring to FIGS. 1-3, FIG. 1 shows a top view of the wiring within the non-displaying region of an array base board in the related art. FIG. 2 shows a sectional view along a direction of AA′ of the non-displaying region in FIG. 1. FIG. 3 shows a diagram of the area of the positions where the lead wires within the non-displaying region are damaged under a microscope. As shown in FIG. 1, the array base board of the thin film transistor liquid crystal display includes, within the displaying region, a plurality of scanning lines (the gate 122 lead wires in FIG. 1) and a plurality of data lines (the source-drain lead wires in FIG. 1) that are arranged in an array, and the regions within the displaying region that are defined by the intersecting scanning lines and data lines are the pixel regions. The data lines are wired in the array base board, extend within the non-displaying region, finally converge to the bonding region, and realize the circuit connection with the driving chip within the bonding region by using a packaging technique. The driving chip is used to supply digital signals to the data lines according to the frames to be displayed. The data lines are connected to the source-drain electrodes of the thin-film transistors. Certainly, in some displays having the function of touch controlling, the displaying region further includes touch-controlling signal lines. The touch-controlling signal lines may also be wired in the array base board, extend within the non-displaying region and finally converge to the bonding region, thus the touch-controlling chip can be used to receive the wiring of the touch-controlling signal lines and realize the function of touch controlling.

The structure of the array base board within the displaying region may refer to the structure of the conventional IPS (In-Plane Switching) display panels or the structure of the VA panels. As shown in FIG. 2, taking the case as an example where the lead wire disposed in the lead-wire layer is the data line, the size of the organic-film-trenching region is 250 μm, and because in the manufacturing process of the array base board, the organic film and the PVX1 layer over the source-drain layer are removed, within the bonding region and its peripheral area, merely the PVX2 layer is reserved over the lead wires. Because the PVX2 layer is thin, it has a poor effect of the protection on the lead wires underneath, and, therefore, the following problems easily emerge:

As the first problem, when the array base board is cut off from the motherboard of the array base board along the cutting line, because that region is adjacent to the cutting line, it is easily crushed by the debris in the cutting. If the mode of double-layer wiring is employed by the lead wires within the non-displaying region, then, under the squeezing by the debris, the two layers of the lead wires are easily short-circuited.

As the second problem, when the COG packaging technique is employed, it is required to wash the surface of the non-displaying region by using plasma, and the lead wires are easily damaged during the washing. Moreover, subsequently, the high-temperature high-humidity long-time reliability water vapor easily enters and easily corrodes the lead wires, which results in cracking of the lead wires. As shown in FIG. 3, within the non-displaying region where the organic film and the PVX1 layer have been removed, i.e., within the region of the length of 250 μm at the periphery of the bonding region, lead-wire cracking happens.

The lead wires are the lead wires of the data lines or the lead wires of the scanning lines, and, for no matter which lead wire, based on the above two problems, there is a case where the lead wire caused by the binding process in the non-display area is corroded and broken, which results in the problem of the display panel of vertical-line imperfect and square-grid imperfect.

In view of the above, an array base board is provided in the present disclosure. By reducing the size of the area at the periphery of the bonding region of the array base board where the organic film and the PVX1 layer are trenched, the area where the lead wires are located that is covered by merely the PVX2 layer is highly reduced, for example, reduced to 30 μm or less. With the reduced size, the risk region that is corroded by water vapor in the packaging process can be reduced, thereby the problem of lead-wire cracking is prevented. Additionally, protecting film layers may also be added at the periphery of the bonding region, thereby the thickness and the layer quantity of the film layers that protect the lead wires underneath are increased to prevent corrosion by water vapor, thus the risk in lead-wire cracking can be highly reduced.

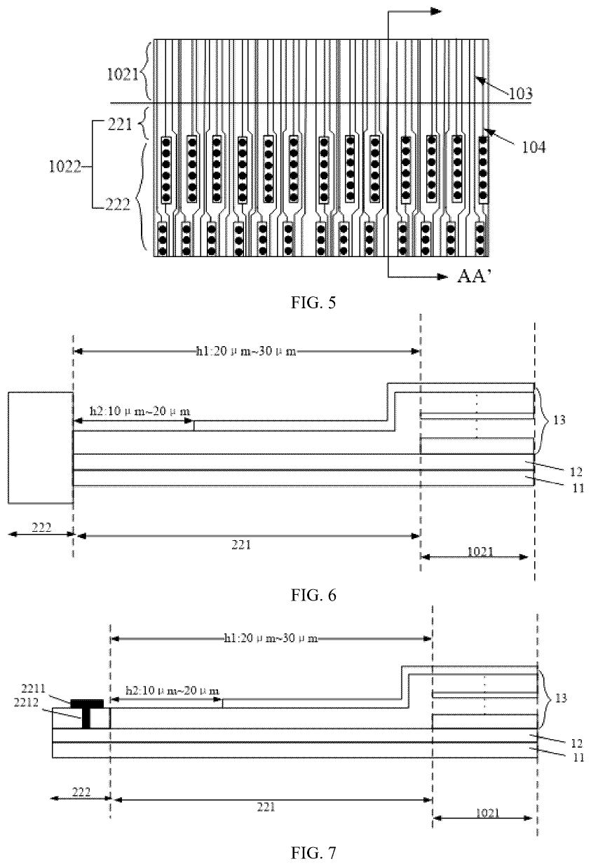

Referring to FIGS. 4-6, FIG. 4 shows a schematic top planar view of an array base board. FIG. 5 shows a schematic top planar view of an array base board according to an embodiment of the present disclosure within the trenching region. FIG. 6 shows a sectional view along the direction of AA′ of the non-displaying region 102 of the array base board. As shown in FIGS. 4-6, the array base board mainly includes a substrate 11.

The substrate 11 is provided with a displaying region 101 and a non-displaying region 102, the non-displaying region 102 includes a lead-wire region 1021 and a trenching region 1022, the trenching region 1022 is located at the side of the lead-wire region 1021 away from the displaying region 101, the trenching region 1022 includes a bonding region 222 and a separating region 221, and the separating region 221 is located between the bonding region 222 and the lead-wire region 1021.

Both of the lead-wire region 1021 and the trenching region 1022 include a lead-wire layer 12 disposed on the substrate 11, the lead-wire region 1021 further includes a plurality of types of protecting film layers 13 that are arranged in layer configuration, and the plurality of types of protecting film layers 13 are located at the side of the lead-wire layer 12 away from the substrate 11.

At least two types of the protecting film layers 13 within the lead-wire region 1021 extend to the separating region 221, and/or the dimension in the target direction of the separating region 221 is greater than or equal to 20 μm, and less than or equal to 30 μm, wherein the target direction refers to the direction from the bonding region 222 pointing to the lead-wire region 1021.

In the present embodiment, the substrate 11 may be a glass substrate 11. The array base board may be an array base board used in an LCD display. The array base board may be an array base board in an ADS (Advanced Dimens In Switch) panel or an IPS panel, or may be an array base board of the HADS (High-Advanced Dimens In Switch) type, or may be an array base board in a TN (Twisted Nematic) panel or a VA (Vertical Alignment) panel, which is not limited particularly herein.

As shown in FIG. 4, the substrate 11 is provided with a displaying region 101 and a non-displaying region 102, the non-displaying region 102 includes a lead-wire region 1021 and a trenching region 1022, the trenching region 1022 includes a separating region 221 and a bonding region 222, and the separating region 221 is used to separate the lead-wire region 1021 and the bonding region 222. As shown in FIG. 5, the lead-wire region 1021 includes a plurality of lead wires. The lead wires are manufactured by using a metal material, which may, for example, be a metal material or an alloy material, to ensure the good electric-conduction performance of the lead wires. The displaying region 101 of the array base board generally includes a plurality of thin-film transistors. For the array base board of the LCD display, the displaying region 101 includes a plurality of pixel regions, and each of the pixel regions includes a thin-film transistor. The gate 122 of the thin-film transistor is connected to a gate line 103, i.e., a scanning line 103, and the source-drain electrode is connected to a data line 104, wherein the source or the drain is connected to the data line 104.

All of the displaying region 101, the lead-wire region 1021 and the trenching region 1022 of the array base board have a lead-wire layer 12. In some cases, the data line 104 and the scanning line 103 may be arranged in the same layer within the displaying region 101, and may not be arranged in the same layer within the lead-wire region 1021. Accordingly, within both of the trenching region 1022 and the lead-wire region 1021, two lead-wire layers 12 are reserved, and the different lead-wire layers 12 may have different lead wires. For example, one of the layers has the lead wire of the data line 104, the other of the layers has the lead wire of the scanning line 103, and the lead wires are separate and insulated therebetween. Accordingly, the data line 104 and the scanning line 103 can be converted from being arranged in the same layer of the displaying region 101 to being arranged in different layers of the lead-wire region 1021.

In some other cases, the data line 104, after exported from the displaying region 101, may be wired in a plurality of film layers within the lead-wire region, for example, wired alternately in two lead-wire layers within the lead-wire region, thereby the wiring spacing is shortened, to save the room. In such a mode of double-layer wiring, more lead wires can be disposed within the limited lead-wire region 1021, which facilitates the design of a narrow-border-frame array base board.

As an example, the lead wire in the lead-wire layer may be electrically connected to the data line within the displaying region, and may be deemed as an exported line of the data line, i.e., the data line connected to the source-drain electrode. Specifically, for the lead wire in the lead-wire layer, the metal in the same layer as the gate or the data line may be used to perform alternate-film-layer wiring.

As an example, the lead wire in the lead-wire layer may also include a lead wire connected to a touch-controlling signal line within the displaying region, and for the touch-controlling signal line, the metal-layer wiring the same as the metal-layer wiring of the data line may be employ. Regardless of the lead wire of the data line or the lead wire of the touch-controlling signal line, both of the tops of the lead-wire layers where those lead wires are located may be protected by using at least two types of the protecting film layers, and/or the dimension in the target direction of the separating region is reduced.

The top of the lead-wire layer 12 within the lead-wire region 1021, i.e., the side of the lead-wire layer 12 away from the substrate 11, includes a plurality of types of protecting film layers 13. The plurality of types of protecting film layers 13 may be considered as the extension of some of the film layers within the displaying region 101 of the array base board, and the some of the extending film layers may be described in detail in the subsequent embodiments.

The trenching region 1022 may be understood as the region that is formed in some of the regions of the lead-wire region 1021 by removing a part of the protecting film layers 13 included by the regions, for example, the region that is formed after the organic film layer 132 within the lead-wire region 1021 is removed.

As an example, all of the corresponding film-layer structures of the trenching region 1022, the lead-wire region 1021 and the displaying region 101 can be formed in one step in the same manufacturing process, therefore, simultaneously with the formation of the displaying region 101, the trenching region 1022 and the lead-wire region 1021 are formed together. Because the film-layer structures within the displaying region 101 of different types of array base boards are different, the process steps for manufacturing the array base boards are different, and the specific differences may be described in detail in the subsequent embodiments. Accordingly, because of the differences in the manufacturing processes of the different types of array base boards, when the trenching region 1022 is formed, the trenched film layers can be different, and, therefore, the film layers that are reserved within the trenching region 1022 can be different.

The bonding region 222 may be a part of the area of the trenching region 1022, wherein the size of the area may be decided according to the bonded peripheral devices and the bonded mode, and, accordingly, the separating region 221 may be the other area than the bonding region 222 within the trenching region. If the peripheral device is a driving chip, when the bonding mode is a top-face bonding mode, it is required to bond the driving chip at the side of the bonding region 222 away from the substrate 11, and, accordingly, the size of the bonding region 222 can be adapted for the driving chip. When the bonding mode is a side-face bonding mode, it is required to bond the driving chip at the side edge of the bonding region 222, i.e., the cut fracture surface of the array base board, and, accordingly, the size of the bonding region 222 can be less than the size of the bonding region using the top-face bonding mode.

In the embodiments of the present disclosure, no matter which manufacturing process is employed by the array base board, when a part of the protecting film layers 13 over the lead-wire layer 12 are trenched off, at least two types of the film layers over the lead-wire layer 12 may be reserved to the largest extent, so that the top of the lead-wire layer 12 within the separating region 221 is protected by the at least two types of the protecting film layers 13, and/or, the size of the trenching region where the protecting film layers 13 are trenched off may be low to the largest extent, so that the dimension in the target direction of the separating region 221 is greater than or equal to 20 μm, and less than or equal to 30 μm.

Accordingly, at least two types of the protecting film layers 13 are arranged in layer configuration at the side of the lead-wire layer 12 within the separating region 221 away from the substrate 11, and, when the separating region 221 includes two lead-wire layers 12, the at least two types of the protecting film layers 13 are arranged at the side of the uppermost lead-wire layer 12 away from the substrate 11.

As shown in FIG. 6, the array base board is required to have the following three configurations:

In the first configuration, at least two types of the protecting film layers 13 within the lead-wire region 1021 extend to the separating region 221. In the second configuration, the dimension in the target direction of the separating region 221 is greater than or equal to 20 μm, and less than or equal to 30 μm. In the third configuration, at least two types of the protecting film layers 13 within the lead-wire region 1021 extend to the separating region 221 and the dimension in the target direction of the separating region 221 is greater than or equal to 20 μm, and less than or equal to 30 μm. By using the first configuration and the third configuration, the thickness of the protecting films over the lead-wire layer 12 within the separating region 221 can be increased, and, with the increased thickness, the high-temperature high-humidity long-time reliability water vapor cannot easily enter and corrode the metal of the lead-wire layer 12. By using the second configuration and the third configuration, the size of the separating region 221 can be reduced, so that the size of the lead-wire layer 12 that is protected by fewer protecting film layers 13 is reduced, and its risk region that is affected by water-vapor corrosion is reduced, thus the risk in water-vapor corrosion on the lead-wire layer 12 can be reduced, and the probability that the lead wires in the lead-wire layer 12 are corroded and crack can be reduced.

As an example, at least one protecting film layer 13 within the lead-wire region 1021 extends to the separating region 221 and fully covers the separating region 221. If merely one protecting film layer 13 within the lead-wire region 1021 extends to the separating region 221, the dimension in the target direction of the separating region 221 is 20 μm-30 μm. If two protecting film layers 13 within the lead-wire region 1021 extend to the separating region 221 and fully cover the separating region 221, the dimension in the target direction of the separating region 221 may be greater than 30 μm, for example, 200 μm-250 μm. If two protecting film layers 13 within the lead-wire region 1021 extend to the separating region 221, and one of the protecting film layers 13 does not fully cover the separating region 221, the dimension in the target direction of the separating region 221 may be 20 μm-30 μm. If more than two protecting film layers 13 within the lead-wire region 1021 extend to the separating region 221, the dimension in the target direction of the separating region 221 may be greater than 30 μm.

As an example, in any of the above-described configurations, the protecting film layers 13 reserved within the separating region 221 may include protecting film layers 13 manufactured by using an inorganic material, for example, an inorganic material such as SiNx and SiOx. The protecting film layers 13 of an inorganic material have better thicknesses and hardnesses, and have better effects of protection and water resistance. Certainly, besides the protecting film layers 13 manufactured by using an inorganic material, the protecting film layers 13 of a metal material may further be included. The metal materials have a good ductility, flexible design of the lead-wire region 1021 and the separating region 221, for example, the design of curved lead-wire region 1021 and separating region 221 can be realized.

The protecting film layers of the metal material may not be manufactured by using a pure metal material, and, in practice, may be manufactured by using materials such as indium tin oxide.

In some alternative examples, the film-layer structures of the bonding region 222 and separating region 221 may be the same or different. If the film-layer structures of the bonding region 222 and separating region 221 are different, the bonding region 222 may include merely the lead-wire layer 12, to expose the lead wires, or the bonding region 222 may include at least one protecting film layer 13 over the lead-wire layer 12, wherein the side of the protecting film layer 13 away from the substrate 11 may be provided with exported electrodes 2211. Referring to FIG. 7, FIG. 7 shows a schematic sectional structural diagram along the direction of AA′ of an array base board. As shown in FIG. 7, the exported electrode 2211 is lap-joined to the lead wire in the lead-wire layer 12 underneath by a through hole 2212 disposed in the protecting film layer 13, therefore the circuit connection between the peripheral devices and the array base board via the lap joining with the exported electrode 2211 can be realized. In such a case, the protecting film layer 13 within the bonding region 222 may be the extension of the at least one protecting film layer 13 within the separating region 221, or may be a protecting film layer 13 independently growing within the bonding region 222, which is not limited herein.

When the array base board according to the present embodiment is used, in the packaging, firstly the surface of the trenching region 1022 is washed. After the washing has been completed, then the peripheral devices are bonded to the bonding region 222; for example, the driving chip is bonded to the bonding region 222. Within the bonding region 222, the leads of the driving chip are lap-joined to the lead wires in the lead-wire layer 12 within the bonding region 222, thereby the circuit connection between the driving chip and the array base board is realized.

Because two types of the protecting film layers 13 are over the lead-wire layer 12 within the separating region 221, when the surface of the trenching region 1022 is washed, the at least two types of the protecting film layers 13 can protect the lead-wire layer 12 within the separating region 221, to prevent water vapor from entering the lead-wire layer 12 and corroding the lead wires. When the dimension of the separating region 221 in the direction from the bonding region 222 pointing to lead-wire region 1021 is greater than or equal to 20 μm, and less than or equal to 30 μm, the area of the separating region 221 can be very low. Accordingly, the risk region where the lead-wire region 1021 is corroded within the separating region 221 is highly reduced, which can reduce the risk in the lead-wire layer 12 being corroded and thus cracking. When the size of the separating region 221 is reduced to below 30 μm and the separating region 221 has at least two types of the protecting film layers 13, the lead-wire layer 12 within the separating region 221 is protected more effectively, thereby the risk in cracking of the lead wires during the packaging is highly reduced, which can prevent the problem of square-grid imperfect and vertical-line imperfect when the display panel is tested.

In an embodiment, the dimension in the target direction of the separating region 221 may be related to the quantity of the protecting film layers 13 that extend to the separating region 221. As an example, the dimension in the target direction of the separating region 221 may increase with the increasing of the quantity of the protecting film layers 13 extending to the separating region 221. For example, if more protecting film layers 13 extend from the lead-wire region 1021 to the separating region 221, the dimension in the target direction of the separating region 221 is higher. That is because, more protecting film layers 13 protect the lead-wire layer 12 within the separating region 221 more effectively. In such a case, the dimension in the target direction of the separating region 221 may be increased, to prevent that, when the peripheral devices are packaged within the bonding region 222, short-distance steps are generated at the periphery of the bonding region 222.

As another example, if fewer protecting film layers 13 extend from the lead-wire region 1021 to the separating region 221, the dimension in the target direction of the separating region 221 is lower. That is because, fewer protecting film layers 13 protect the lead-wire layer 12 within the separating region 221 less effectively. In such a case, the dimension in the target direction of the separating region 221 may be reduced, to reduce the risk region where the lead-wire layer 12 is corroded by water vapor, thereby the probability that the lead-wire layer 12 is corroded is reduced.

In an alternative example of the present embodiment, the dimension in the target direction of the separating region 221 may be in the range of 20 μm-250 μm, and increases with the increasing of the quantity of the protecting film layers 13 extending to the separating region 221. In an alternative example, the dimension in the target direction of the separating region 221 may also be in the range of 20 μm-25 μm, and increases with the increasing of the quantity of the protecting film layers 13 extending to the separating region 221. When the dimension varies in the former range of 20 μm-250 μm, the dimension in the target direction of the separating region 221 can flexibly have various configurations, to satisfy the diversified demands on the protection on the lead-wire layer 12. When the dimension varies in the later range of 20 μm-250 μm, the corrosion risk region can be reduced, to ensure to the largest extent that the lead wires in the lead-wire layer 12 cannot be corroded.

In another alternative example of the present embodiment, when the quantity of the protecting film layers 13 extending from the lead-wire region 1021 to the separating region 221 is greater than or equal to three types, the lead-wire layer 12 has already been protected well. In such a case, the dimension in the target direction of the separating region 221 may not be limited to below 30 μm, and may be greater than 30 μm. When the dimension in the target direction of the separating region is greater than 30 μm, the periphery of the bonding region 222 can have the separating region 221 of a large size, and when the bonding region 222 is bonded to the peripheral devices, it can be prevented that large steps are generated within the peripheral region closer to the bonding region 222.

Accordingly, in practice, when at least three types of the protecting film layers 13 extend to the separating region 221, the dimension in the target direction of the separating region 221 may be greater than or equal to 200 μm, and less than or equal to 250 μm.

When two types of the protecting film layers 13 extend to the separating region 221, the dimension in the target direction of the separating region 221 is greater than or equal to 20 μm, and less than or equal to 30 μm.

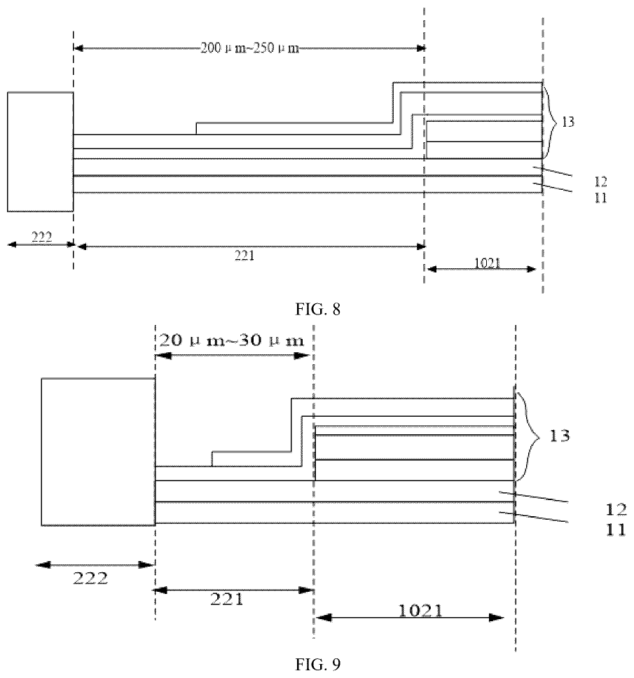

As an example, referring to FIGS. 8 and 9, FIG. 8 shows a sectional view along the direction of AA′ of the array base board when the separating region 221 includes three types of the protecting film layers 13. FIG. 9 shows a sectional view along the direction of AA′ of the array base board when the separating region 221 includes two types of the protecting film layers 13. As shown in FIG. 8, when three types of the protecting film layers 13 are included, three types of the protecting film layers 13 are over the lead-wire layer 12 within the separating region 221. Accordingly, the three types of the protecting film layers 13 block water vapor from entering, and, even with long-time water-vapor infiltration, the lead-wire layer 12 underneath can still be protected, to prevent corrosion on the lead-wire layer 12 by water vapor. With such a configuration that the dimension in the target direction of the separating region 221 is greater than or equal to 200 μm, and less than or equal to 250 μm, when the peripheral devices are being bonded to the bonding region 222, for example, the driving chip is bonded to the bonding region 222, a region of a relatively large size that is not highly different from the height of the position of the bonding region 222 can exist at the periphery of the bonding region 222, which prevents that large steps are generated at the position adjacent to the bonding region 222, thereby the peripheral devices is prevented from crushing the devices within the lead-wire region 1021 due to steps of a low distance, so as to improve the quality of the bonding.

As shown in FIG. 9, two types of the protecting film layers 13 within the lead-wire region 1021 extend to the separating region 221. In such a configuration, merely two types of the protecting film layers 13 are over the lead-wire layer 12 within the separating region. Accordingly, as compared with the configuration of three types of the protecting film layers 13, it has a poorer effect of the blocking of long-time water-vapor infiltration. Accordingly, the risk in water-vapor corrosion on the lead-wire layer 12 may be reduced by reducing the size of the separating region 221. For example, the dimension in the target direction of the separating region 221 may be set to be greater than or equal to 20 μm, and less than or equal to 30 μm. Accordingly, because the size of the lead-wire layer 12 that has merely two types of the protecting film layers 13 is reduced, its risk region that is affected by water-vapor corrosion is reduced, thus the risk in water-vapor corrosion on the lead-wire layer 12 is reduced. As an example, the dimension in the target direction of the separating region 221 may be 25 μm. 25 μm can satisfy preventing generation of large steps when the peripheral devices are being bonded within the bonding region 222, to satisfy the most basic requirement on the bonding.

In the present embodiment, in an example, at least three types of the protecting film layers 13 within the lead-wire region 1021 extend to the separating region 221, the at least three types of the film layers may not include the organic film layer 132, and the dimension in the target direction of the separating region 221 may be 250 μm or 200 μm or 225 μm. The at least three types of the film layers may not include the organic film layer 132. Specifically, the protecting film layers 13 extending to the separating region 221 include at least a thin-film layer and an inorganic film layer. According to practical situations, the protecting film layers 13 extending to the separating region 221 may include two types of the thin-film layer, or include two types of the inorganic film layer. Alternatively, both of the thin-film layer and the inorganic film layer may be two types.

The thin-film layer may be manufactured by using the material of indium tin oxide.

In another example, merely two types of the protecting film layers 13 within the lead-wire region 1021 extend to the separating region 221. The two types of the film layers may not include the organic film layer 132. The two types of the film layers may include a thin-film layer manufactured by using the material of indium tin oxide and an inorganic film layer. The dimensions in the target direction of the separating regions 221 may be 30 μm or 20 μm or 25 μm. Certainly, preferably, it may be 25 μm.

The array base boards of the above-described three configurations will be described individually below:

Firstly, the lead-wire region 1021 of the array base board includes a plurality of types of protecting film layers 13. In fact, according to the film-layer structure of the displaying region 101 of the array base board, the structure of the protecting film layers 13 of the array base board of the lead-wire region 1021 may be slightly different.

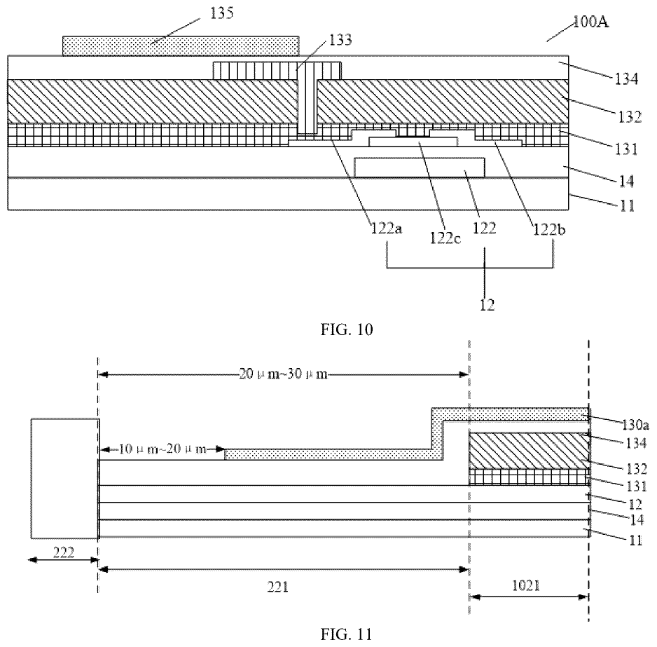

Referring to FIG. 10, FIG. 10 shows a schematic sectional structural diagram of the displaying region 101 of an array base board A. As shown in FIG. 10, the displaying region 101 includes:
a substrate 11;
a gate 122 located on the substrate 11, a gate insulating layer 14 located at the side of the gate 122 away from the substrate 11, and an active layer 122c located at the side of the gate insulating layer 14 away from the substrate 11;
a source 122b and a drain 122a that are located at the side of the active layer 122c away from the substrate 11 and are lap-joined to a doped region of the active layer 122c;
a first passivating layer 131 located at the side of the source-drain electrode 122a away from the substrate 11;
a pixel electrode 133 located at the side of the first passivating layer 131 away from the substrate 11;
an organic film layer 132 located at the side of the pixel electrode 133 away from the substrate 11;
a second passivating layer 134 located at the side of the organic film layer 132 away from the substrate 11; and
a common electrode 135 located at the side of the second passivating layer 134 away from the substrate 11.

The pixel electrode 133 may be a plate electrode. The common electrode 135 may be a slit electrode. The common electrode 135 may be formed after the formation of the pixel electrode 133. The array base board of such a type may be referred to as the design of Top com.

Both of the pixel electrode 133 and the common electrode 135 may be manufactured by using a transparent metal material, for example, indium tin oxide ITO. The pixel electrode 133 is lap-joined to the drain 122a via a through hole provided in the first passivating layer 131. The thicknesses of the first passivating layer 131 and the second passivating layer 134 may be 1000-5000 A (angstroms). The organic film layer 132 generally has a higher thickness, which may be 20000 A-25000 A.

The organic film layer 132 serves to cushion between the pixel electrode 133 and the second passivating layer 134, and is mainly used to protect the pixel electrode 133. In the manufacturing of the array base board of such a type, because the pixel electrode 133 requires being lap-joined to the drain 122a underneath via the through hole in the first passivating layer 131, it is required to perforate the first passivating layer 131. Accordingly, when the organic films are trenched off within the trenching region 1022, considering the simplicity of the process procedure, the first passivating layer 131 is also trenched off, and, in turn, simultaneously with the removal of the organic films, the first passivating layer 131 at the corresponding position is also removed. Therefore, within the trenching region 1022, the first passivating layer 131 does not exist.

In the exemplary array base board A shown in FIG. 10, the displaying region 101 of the array base board may include a plurality of pixel units arranged in an array, and each of the pixel units includes a pixel electrode 133, a common electrode 135 and a thin-film transistor. The pixel electrode 133 is electrically connected to a source-drain electrode of the thin-film transistor, and the common electrode 135 is located at the side of the pixel electrode 133 away from the substrate 11. The first thin-film layer 130a and the common electrode 135 are arranged in the same layer.

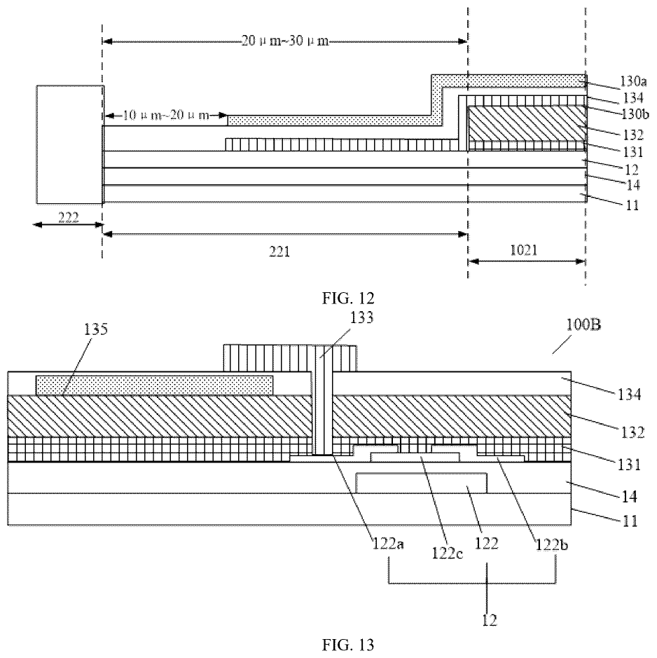

Accordingly, the protecting film layers 13 over the lead-wire layer 12 within the lead-wire region 1021 may be a part or a whole of the film layers within the displaying region 101 other than the gate 122 and the source-drain electrode 122a. Referring to FIGS. 11 and 12, FIG. 11 shows a schematic sectional structural diagram along the direction of AA′ of an array base board A. FIG. 12 shows a schematic sectional structural diagram along the direction of AA′ of an array base board A. The quantities of the protecting film layers 13 within the lead-wire regions 1021 of the array base boards shown in FIGS. 11 and 12 are unequal, and, correspondingly, the film-layer structures formed by the protecting film layers 13 are different slightly.

As shown in FIG. 11, the plurality of types of protecting film layers 13 within the lead-wire region 1021 include the following film layers:
a first passivating layer 131 located at the side of the lead-wire layer 12 away from the substrate 11;
an organic film layer 132 located at the side of the first passivating layer 131 away from the substrate 11;
a second passivating layer 134 located at the side of the organic film layer 132 away from the substrate 11; and
a first thin-film layer 130a located at the side of the second passivating layer 134 away from the substrate 11.

The array base board, within the lead-wire region 1021, besides the substrate 11, may further include a gate insulating layer. The gate insulating layer within the lead-wire region 1021 and the gate insulating layer within the displaying region 101 may be arranged in the same layer, i.e., formed in a one-step film-formation process. The lead-wire layer 12 and the gate insulating layer within the lead-wire region 1021 are insulated from each other.

The plurality of lead wires disposed in the lead-wire layer 12 within the lead-wire region 1021 include the lead wire connected to the drain 122a and the lead wire connected to the gate 122, and the two types of lead wires may be arranged in the same layer and have a gap therebetween. The materials of the lead wires and the electrodes connected thereto (the drain 122a and the gate 122) may be the same.

The first passivating layer 131 within the lead-wire region 1021 may be in the same layer as and of the same material as the first passivating layer 131 within the displaying region 101. The organic film layer 132 may be disposed in the same layer as and of the same material as the organic film layer 132 within the displaying region 101. The second passivating layer 134 may be disposed in the same layer as and of the same material as the second passivating layer 134 within the displaying region 101.

The first thin-film layer 130a may be disposed in the same layer as the common electrode 135, and the material of the common electrode 135 may be employed as the material of the first thin-film layer 130a, thus they can be formed in a one-step film-formation process.

Accordingly, there are totally 4 types of the protecting film layers 13 over the lead-wire layer 12 within the lead-wire region 1021.

In another type of the exemplary array base board shown in FIG. 11, the thickness of the first passivating layer 131 is greater than the thickness of the first thin-film layer 130a, and/or the thickness of the second passivating layer 134 is greater than the thickness of the first thin-film layer 130a.

In the present alternative example, the thickness of the first passivating layer 131 within the lead-wire region 1021 may be greater than the thickness of the first thin-film layer 130a, or the thickness of the second passivating layer 134 within the lead-wire region 1021 may be greater than the thickness of the first thin-film layer 130a. Alternatively, the thickness of the first passivating layer 131 within the lead-wire region 1021 is greater than the thickness of the first thin-film layer 130a, and the thickness of the second passivating layer 134 within the lead-wire region 1021 may be greater than the thickness of the first thin-film layer 130a.

As shown in FIG. 12, FIG. 12 shows another sectional structure of the lead-wire region 1021 of the array base board A shown in FIG. 10. The lead-wire region 1021 of this type of the array base board includes the following film layers:
a first passivating layer 131 located at the side of the lead-wire layer 12 away from the substrate 11;
an organic film layer 132 located at the side of the first passivating layer 131 away from the substrate 11;
a second thin-film layer 130b located at the side of the organic film layer 132 away from the substrate 11;
a second passivating layer 134 located at the side of the second thin-film layer 130b away from the substrate 11; and
a first thin-film layer 130a located at the side of the second passivating layer 134 away from the substrate 11.

In the array base board A shown in FIG. 10, the displaying region 101 may include a plurality of pixel units arranged in an array, and each of the pixel units includes a pixel electrode 133, a common electrode 135 and a thin-film transistor. The pixel electrode 133 is electrically connected to a source-drain electrode of the thin-film transistor, and the common electrode 135 is located at the side of the pixel electrode 133 close to the substrate 11.

Both of the first thin-film layer 130a and the second thin-film layer 130b may be manufactured by using the material of indium tin oxide, which cannot only ensure a certain ductility of the separating region, but also can prevent corrosion on the thin-film layer in the reliability process.

As compared with the lead-wire region 1021 shown in FIG. 11, the lead-wire region 1021 in FIG. 12 further includes the second thin-film layer 130b. The second thin-film layer 130b may be disposed in the same layer as the pixel electrode 133 within the displaying region 101 shown in FIG. 10, and the material of the pixel electrode 133 may be employed as the material of the second thin-film layer 130b, therefore the pixel electrode 133 and the second thin-film layer 130b can be formed in a one-step film-formation process.

Whether it is the lead-wire region 1021 shown in FIG. 11 or the lead-wire region 1021 shown in FIG. 12, the materials of the first passivating layer 131 and the second passivating layer 134 may be SiNx or SiOx. The organic film layer 132 may be a high-molecular polymer material, for example, cellulose derivatives, polyimides and silicon containing polymers. The thickness of the organic film layer 132 may be 20000-30000 A, and the thicknesses of the first thin-film layer 130a and the second thin-film layer 130b may be 500-1000 A, therefore the thicknesses of the pixel electrode 133 and the common electrode 135 may also be 500-1000 A.

As shown in FIGS. 11 and 12, because the quantities and the structures of the protecting film layers 13 within the lead-wire regions 1021 of the array base boards may be slightly different, the protecting film layers 13 extending from the lead-wire region 1021 to the separating region 221 and the dimension in the target direction of the separating region 221 may be configured in many modes, so as to protect the lead-wire layer 12 more effectively.

As shown in FIG. 11, the plurality of types of protecting film layers 13 within the lead-wire region 1021 may include four types of the protecting film layers 13; in other words, the plurality of types of protecting film layers 13 within the lead-wire region 1021 include the following film layers: the first passivating layer 131, the organic film layer 132, the second passivating layer 134 and the first thin-film layer 130a. The two types of the protecting film layers 13 within the lead-wire region 1021 extend to the separating region 221. Specifically, the second passivating layer 134 and the first thin-film layer 130a extend to the separating region 221, the second passivating layer 134 covers the separating region 221, and there is a gap between the first thin-film layer 130a and the bonding region 222.

As shown in FIG. 11, there is a gap between the first thin-film layer 130a and the bonding region 222. In this way, the problem that the bonding region 222 and the first thin-film layer 130a are electrically connected to result in short circuiting can be avoided. For example, when the first thin-film layer 130a is lap-joined to the lead-wire layer 12 underneath, when the first thin-film layer 130a is also lap-joined to the bonding region 222, then the first thin-film layer 130a and the bonding region 222 are short-circuited.

When the second passivating layer 134 and the first thin-film layer 130a extend to the separating region 221, the dimension of the separating region 221 may be greater than or equal to 25 μm, and less than or equal to 30 μm. Alternatively, the dimension of the separating region may be greater than 30 μm, and be in the range of 200 μm-250 μm.

In an alternative example of the present embodiment, no matter which dimension interval described above the separating region 221 is in, because there is a gap between the first thin-film layer 130a and the bonding region 222, the spacing between the bonding region 222 and the first thin-film layer 130a may be greater than or equal to 10 μm, and less than or equal to 20 μm. As shown in FIG. 11, although there is a gap between the first thin-film layer 130a and the bonding region 222, their gap distance is 10 μm-20 μm, thus the protection on the lead-wire layer 12 can be improved, so that the risk region over the lead-wire layer 12 that is covered by fewer protecting film layers 13 is small, to protect the lead-wire layer 12 more effectively.

In an alternative example of the present embodiment, as stated above, when two types of the protecting film layers 13 within the lead-wire region 1021 extend to the separating region 221, the dimension in the target direction of the separating region 221 may be greater than or equal to 20 μm, and less than or equal to 30 μm. As shown in FIG. 11, in such a case, the separating region 221 has a sufficiently low size, and, therefore, the risk region where the lead-wire layer 12 is corroded due to water-vapor infiltration is reduced. When the risk region is reduced, the possibility that the lead-wire layer 12 is corroded is reduced, thus the problem that the lead-wire layer 12 is corroded and thus cracks can be effectively prevented.

In another embodiment, as shown in FIG. 12, the lead-wire region 1021 includes five types of the protecting film layers 13, which are the first passivating layer 131, the organic film layer 132, the second thin-film layer 130b, the second passivating layer 134 and the first thin-film layer 130a. In the array base board of such a type, besides that the second passivating layer 134 and the first thin-film layer 130a extend to the separating region 221, the second thin-film layer 130b further extends to the separating region 221, and there is a gap between the second thin-film layer 130b and the bonding region 222.

As stated above, as the quantity of the film layers extending to the separating region 221 increases, the target size of the separating region 221 may gradually increase. As an example, when the second passivating layer 134 and the first thin-film layer 130a extend to the separating region 221, the dimension in the target direction of the separating region 221 may be greater than or equal to 20 μm, and less than or equal to 30 μm. When the second passivating layer 134, the first thin-film layer 130a and the second thin-film layer 130b extend to the separating region 221, the dimension in the target direction of the separating region 221 may be greater than or equal to 200 μm, and less than or equal to 250 μm.

Alternatively, the dimension in the target direction of the separating region 221 may be changed in the range of 20 μm-30 μm. For example, when the second passivating layer 134 and the first thin-film layer 130a extend to the separating region 221, the dimension in the target direction of the separating region 221 may be equal to 20 μm. When the second passivating layer 134, the first thin-film layer 130a and the second thin-film layer 130b extend to the separating region 221, the dimension in the target direction of the separating region 221 may be equal to 30 μm.

Alternatively, as another example, when the second passivating layer 134 and the first thin-film layer 130a extend to the separating region 221, the dimension in the target direction of the separating region 221 may be equal to 20 μm. When the second passivating layer 134, the second thin-film layer 130b and the first thin-film layer 130a extend to the separating region 221, the dimension in the target direction of the separating region 221 may be equal to 25 μm.

Alternatively, as another example, when the second passivating layer 134 and the first thin-film layer 130a extend to the separating region 221, the dimension in the target direction of the separating region 221 may be equal to 25 μm. When the second passivating layer 134, the second thin-film layer 130b and the first thin-film layer 130a extend to the separating region 221, the dimension in the target direction of the separating region 221 may be equal to 30 μm.

In another alternative example of the present embodiment, because the dimension in the target direction of the separating region 221 may increase with the increasing of the protecting film layers 13 within the separating region 221, when the separating region 221 includes the first thin-film layer 130a and the second thin-film layer 130b, the spacing from the first thin-film layer 130a to the bonding region 222 and the spacing from the second thin-film layer 130b to the bonding region 222 may be related to the dimension in the target direction of the separating region 221.

As an example, when the dimension in the target direction of the separating region 221 is 200 μm-250 μm, then the spacing between the second thin-film layer 130b and the bonding region 222 may be 45 μm-80 μm. For example, the spacing between the second thin-film layer 130b and the bonding region 222 may be 45 μm, or may be 80 μm.

As another example, the spacing between the second thin-film layer 130b and the bonding region 222 is greater than or equal to 10 μm, and less than or equal to 20 μm. The spacing between the first thin-film layer 130a and the bonding region 222 is greater than or equal to 10 μm, and less than or equal to 20 μm.

The spacing from the first thin-film layer 130a to the bonding region 222 and the spacing from the second thin-film layer 130b to the bonding region 222 may be unequal or equal. If they are unequal, the spacing between the first thin-film layer 130a and the bonding region 222 may be greater than the spacing between the second thin-film layer 130b and the bonding region 222. In such a case, when the surface of the trenching region 1022 is washed, the area of the region where the second passivating layer 134 directly contacts the washing liquid can be reduced, thereby the risk region of corrosion on the lead-wire layer 12 underneath is reduced.

Alternatively, as an example, the spacing between the first thin-film layer 130a and the bonding region 222 may be less than the spacing between the second thin-film layer 130b and the bonding region 222. In such a case, when the surface of the trenching region 1022 is washed, the area of the region where the first thin-film layer 130a directly contacts the washing liquid can be reduced, to prevent corrosion on the first thin-film layer 130a within a large area in the washing, which results in residues. Moreover, because the spacing between the second thin-film layer 130b and the bonding region 222 is low, the risk region of corrosion on the lead-wire layer 12 underneath can be reduced. Moreover, because the top of the second thin-film layer 130b is protected by the second passivating layer 134, the risk in corrosion on the second thin-film layer 130b can be reduced.

Referring to FIG. 13, FIG. 13 shows a schematic sectional structural diagram of the displaying region 101 of another array base board B. In this array base board, the pixel electrode 133 within the displaying region 101 is electrically connected to the source-drain electrode of the thin-film transistor, and the common electrode 135 is closer to the substrate 11 than the pixel electrode 133 is.

As shown in FIG. 13, the displaying region 101 may include:
a substrate 11;
a gate 122 located on the substrate 11;
a gate insulating layer 14 located at the side of the gate 122 away from the substrate 11;
an active layer 122c located at the side of the gate insulating layer 14 away from the substrate 11;
a source 122b and a drain 122a that are located at the side of the active layer 122c away from the substrate 11 and are lap-joined to a doped region of the active layer 122c;
a first passivating layer 131 located at the side of the source-drain electrode 122a away from the substrate 11;
an organic film layer 132 located at the side of the first passivating layer 131 away from the substrate 11;
a common electrode 135 located at the side of the organic film layer 132 away from the substrate 11;
a second passivating layer 134 located at the side of the common electrode 135 away from the substrate 11; and
a pixel electrode 133 located at the side of the second passivating layer 134 away from the substrate 11.

The pixel electrode 133 is lap-joined to the drain 122a underneath via the through hole disposed in the first passivating layer 131, the second passivating layer 134 and the organic film layer 132. Accordingly, when the array base board of this type is manufactured, when the organic film layer 132, the first passivating layer 131 and the second passivating layer 134 are trenched, it is required to avoid the common electrode 135. In practice, the organic film may be etched by using a single mask, and the first passivating layer 131 and the second passivating layer 134 may be etched by using the same mask. Accordingly, when the organic film is trenched off, the structure of the first passivating layer 131 and the structure of the second passivating layer 134 may be the same; in other words, the first passivating layer 131 can also extend to the separating region 221.

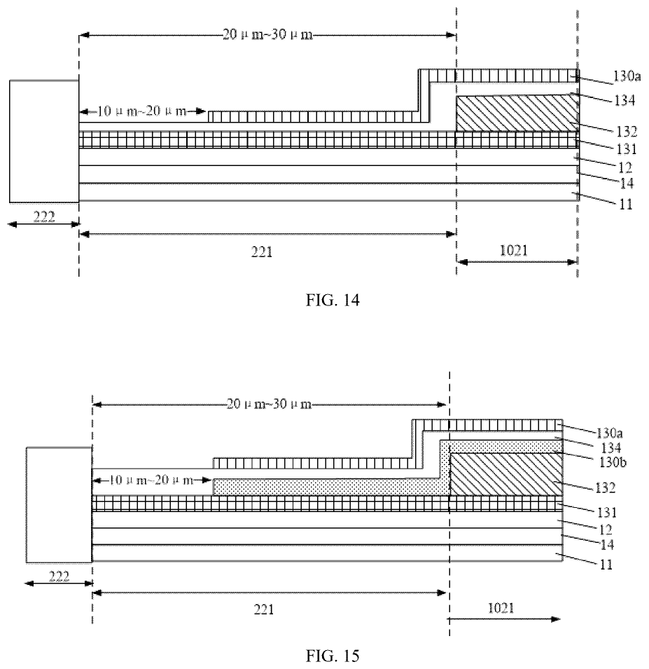

In an alternative example of the array base board B shown in FIG. 13, referring to FIG. 14, the plurality of types of protecting film layers 13 within the lead-wire region 1021 may sequentially include: the first passivating layer 131, the organic film layer 132, the second passivating layer 134 and the first thin-film layer 130a. In another alternative example of the array base board B shown in FIG. 13, as shown in FIG. 15, the plurality of types of protecting film layers 13 within the lead-wire region 1021 may include: the first passivating layer 131, the organic film layer 132, the second thin-film layer 130b, the second passivating layer 134 and the first thin-film layer 130a.

It should be noted that, as different from the array base board A shown in FIG. 10, in the array base board B of such a type, the first thin-film layer 130a and the pixel electrode 133 within the lead-wire region 1021 are arranged in the same layer, and the second thin-film layer 130b and the common electrode 135 are arranged in the same layer. The film-layer thicknesses and the materials of the first passivating layer 131, the second thin-film layer 130b, the organic film layer 132, the second passivating layer 134 and the first thin-film layer 130a in the array base board B shown in FIG. 13 may refer to the thicknesses and the materials of the relative film layers in the array base board A shown in FIG. 10, and are not discussed further herein.

In an alternative example of the array base board B shown in FIG. 13, referring to FIG. 14, FIG. 14 shows a schematic sectional structural diagram along the direction of AA′ of an array base board B. As shown in FIG. 14, the array base board, within the lead-wire region 1021, besides the substrate 11 and the lead-wire layer 12, may further include a gate insulating layer 14. The gate insulating layer 14 within the lead-wire region 1021 and the gate insulating layer 14 within the displaying region 101 may be arranged in the same layer, i.e., formed in a one-step film-formation process. Besides that the second passivating layer 134 and the first thin-film layer 130a extend to the separating region 221, the first passivating layer 131 within the lead-wire region 1021 further extends to the separating region 221, and the first passivating layer 131 covers the separating region 221. There is also a gap between the first thin-film layer 130a and the bonding region 222.

In a further alternative example of the present alternative example, when the separating region 221 includes the first passivating layer 131, the second passivating layer 134 and the first thin-film layer 130a, the dimension in the target direction of the separating region 221 may also be reduced. For example, the dimension in the target direction of the separating region 221 may be greater than or equal to 20 μm, and less than or equal to 30 μm. Optionally, the dimension in the target direction of the separating region may be 25 μm or 30 μm.

The spacing between the first thin-film layer 130a and the bonding region 222 may be decided according to the dimension in the target direction of the separating region 221. When the dimension in the target direction of the separating region 221 is 20 μm-30 μm, then the spacing between the first thin-film layer 130a and the bonding region 222 may be 10 μm-20 μm. When the dimension in the target direction of the separating region 221 is 200 μm-250 μm, then the spacing between the first thin-film layer 130a and the bonding region 222 may be 45 μm-80 μm. For example, the spacing between the first thin-film layer 130a and the bonding region 222 may be 45 μm, or may be 80 μm.

In the array base board according to the present example, the protecting film layers 13 within the lead-wire region 1021 increase, and, accordingly, the quantity of the protecting film layers 13 extending to the separating region 221 can also increase, so that the separating region 221 can have three or more types of the protecting film layers 13, which can improve the protection on the lead-wire layer 12, to prevent corrosion on the lead wires in the lead-wire layer 12 by water vapor.

As shown in FIG. 15, FIG. 15 shows a schematic sectional structural diagram along the direction of AA′ of the array base board B shown in FIG. 13. As shown in FIG. 15, in an alternative example of the present embodiment, besides that the first passivating layer 131, the second passivating layer 134 and the first thin-film layer 130a extend to the separating region 221, the second thin-film layer 130b also extends into the separating region 221. The second thin-film layer 130b, as similar to the first thin-film layer 130a, has a gap with the bonding region 222.

The spacing between the second thin-film layer 130b and the bonding region 222 may be decided according to the dimension in the target direction of the separating region 221. When the dimension in the target direction of the separating region 221 is 20 μm-30 μm, then the spacing between the second thin-film layer 130b and the bonding region 222 may be 10 μm-20 μm. When the dimension in the target direction of the separating region 221 is 200 μm-250 μm, the spacing between the second thin-film layer 130b and the bonding region 222 may be 45 μm-80 μm. For example, the spacing between the second thin-film layer 130b and the bonding region 222 may be 45 μm, or may be 80 μm.

In some other examples, the spacing between the first thin-film layer 130a and the bonding region 222 may be equal to or unequal to the spacing between the second thin-film layer 130b and the bonding region 222. The specific configurations may be referred to the above description on the first thin-film layer 130a and the second thin-film layer 130b in FIG. 12, and are not limited herein.

In the array base board B according to the present example, the protecting film layers 13 within the lead-wire region 1021 are increased to five types, and, correspondingly, the protecting film layers 13 within the separating region 221 are increased to four types. Therefore, the protection on the lead-wire layer 12 can be improved and corrosion on the lead wires in the lead-wire layer 12 by water vapor is prevented.

As stated above, as the quantity of the film layers extending to the separating region 221 increases, the target size of the separating region 221 may gradually increase. As an example, the dimension in the target direction of the separating region 221 may vary in the range of 200 μm-250 μm. For example, when the separating region 221 includes the second passivating layer 134 and the first thin-film layer 130a, the dimension in the target direction of the separating region 221 may be greater than or equal to 200 μm. When the second passivating layer 134, the first passivating layer 131 and the first thin-film layer 130a extend to the separating region 221, the dimension in the target direction of the separating region 221 may also be greater than or equal to 225 μm, and less than or equal to 250 μm. When the second passivating layer 134, the first passivating layer 131, the first thin-film layer 130a and the second thin-film layer 130b extend to the separating region 221, the dimension in the target direction of the separating region 221 may also be equal to 250 μm.

As stated above, when the separating region 221 has three or more types of the protecting film layers 13 for protecting the lead-wire layer 12, the dimension in the target direction of the separating region 221 may also be reduced. As shown in FIGS. 14 and 15, the dimension in the target direction of the separating region 221 may be greater than or equal to 20 μm, and less than or equal to 30 μm. Optionally, the dimension in the target direction of the separating region may be 25 μm or 30 μm.

As an example, the dimension in the target direction of the separating region 221 may vary in the range of 20 μm-30 μm, so as to increase with the increasing of the protecting film layers 13. For example, when the separating region 221 includes the second passivating layer 134 and the first thin-film layer 130a, in such a case, the second passivating layer 134 is not trenched off when the trenching region is formed, and the dimension in the target direction of the separating region 221 may be greater than or equal to 20 μm. When the second passivating layer 134, the first passivating layer 131 and the first thin-film layer 130a extend to the separating region 221, the dimension in the target direction of the separating region 221 may also be greater than or equal to 25 μm, and less than or equal to 30 μm. When the second passivating layer 134, the first passivating layer 131, the first thin-film layer 130a and the second thin-film layer 130b extend to the separating region 221, the dimension in the target direction of the separating region 221 may also be equal to 30 μm.

Alternatively, when the second passivating layer 134 and the first thin-film layer 130a extend to the separating region 221, the dimension in the target direction of the separating region 221 may be equal to 20 μm. When the second passivating layer 134, the first passivating layer 131, the first thin-film layer 130a and the second thin-film layer 130b extend to the separating region 221, the dimension in the target direction of the separating region 221 may be equal to 25 μm. When the second passivating layer 134, the first passivating layer 131, the first thin-film layer 130a and the second thin-film layer 130b extend to the separating region 221, the dimension in the target direction of the separating region 221 may also be equal to 30 μm.

For the LCD display device, it includes a plurality of types of display devices. The above-described array base board A and array base board B are the cases where both of the common electrode 135 and the pixel electrode 133 are disposed on the array base board; in other words, the common electrode 135 and the pixel electrode 133 are located at the same side of the liquid-crystal layer. In fact, there are LCD display devices of other types, and in the LCD display devices of those types, the common electrode 135 and the pixel electrode 133 are located at the two opposite sides of the liquid-crystal layer. In general, the pixel electrode 133 is on the array base board, and the common electrode 135 is located on the cell-assembling base board. The array base board of such a type may be referred to as an array base board C. The structure within the displaying region 101 of the array base board C may refer to the structure within the displaying region 101 of the array base boards in the related art. For example, the structure within the displaying region 101 of the array base board includes a substrate 11, a gate 122 located on the substrate 11, a gate insulating layer 14 located on the gate 122, an active layer 122c located on the gate insulating layer 14, a source-drain layer located on the active layer 122c, a passivating layer located on the source-drain layer, an organic film layer 132 located on the passivating layer, and a pixel electrode 133 located on the organic film layer 132.

In the array base board C of such a type, the lead-wire region 1021 still includes the lead-wire layer 12. The lead-wire layer 12 includes the lead wire connected to the gate 122 and the lead wire connected to the source-drain electrode. The plurality of types of protecting film layers 13 of the lead-wire layer 12 may still have the film-layer structures shown in any one of FIGS. 11, 12, 14 and 15. The configuration of the plurality of types of protecting film layers 13 within the separating region may be referred to the film-layer structures shown in any one of FIGS. 11, 12, 14 and 15. Specifically, the first thin-film layer 130a or the second thin-film layer 130b within the lead-wire region 1021 may be disposed in the same layer as the pixel electrode 133, and the first passivating layer 131 or the second passivating layer 134 may be disposed in the same layer as the passivating layer within the displaying region 101. Moreover, for the extra protecting film layers 13 within the lead-wire region 1021 as compared with the displaying region 101, they may be manufactured correspondingly when the array base board is manufactured, for example, by using a mask, newly adding one passivating layer and one thin-film layer manufactured by using the material of indium tin oxide.

As an example, a preferable array base board D is provided by the present disclosure. The array base board D may, within the displaying region 101, include: a substrate 11; a gate 122 located on the substrate 11; a gate insulating layer 14 located at the side of the gate 122 away from the substrate 11; an active layer 122c located at the side of the gate insulating layer 14 away from the substrate 11; a source 122b and a drain 122a that are located at the side of the active layer 122c away from the substrate 11 and are lap-joined to a doped region of the active layer 122c; a first passivating layer 131 located at the side of the source-drain electrode 122a away from the substrate 11; an organic film layer 132 located at the side of the first passivating layer 131 away from the substrate 11; a common electrode 135 located at the side of the organic film layer 132 away from the substrate 11; a second passivating layer 134 located at the side of the common electrode 135 away from the substrate 11; and a pixel electrode 133 located at the side of the second passivating layer 134 away from the substrate 11. The pixel electrode 133 is lap-joined to the drain 122a underneath via the through hole disposed in the first passivating layer 131, the second passivating layer 134 and the organic film layer 132.

The array base board D may, within the lead-wire region 1021, include: a substrate 11, a gate insulating layer 14 located on the substrate 11, and a lead-wire layer 12 located on the gate insulating layer 14; a first passivating layer 131 located at the side of the lead-wire layer 12 away from the substrate 11; an organic film layer 132 located at the side of the first passivating layer 131 away from the substrate 11; a second thin-film layer 130b located at the side of the organic film layer 132 away from the substrate 11; a second passivating layer 134 located at the side of the second thin-film layer 130b away from the substrate 11; and a first thin-film layer 130a located at the side of the second passivating layer 134 away from the substrate 11. The second thin-film layer 130b and the common electrode 135 are arranged in the same layer, and the first thin-film layer 130a and the pixel electrode 133 are arranged in the same layer.

The array base board D may, within the separating region 221, include: a first passivating layer 131 located over the lead-wire layer 12, a second thin-film layer 130b located over the first passivating layer 131, a second passivating layer 134 located over the second thin-film layer 130b, and a first thin-film layer 130a located over the second passivating layer 134. Both of the first passivating layer 131 and the second passivating layer 134 fully cover the separating region 221.

The array base board D may, within the bonding region 222, include: a first passivating layer 131 located over the lead-wire layer 12, and an exported electrode 2211 located over the first passivating layer 131. The exported electrode 2211 is lap-joined to the lead wire in the lead-wire layer 12 via a hole disposed in the first passivating layer 131.

The dimension in the target direction of the separating region 221 may be 20 μm-30 μm, for example, 25 μm. There are gaps between the first thin-film layer 130a and the bonding region 222 and between the second thin-film layer 130b and the bonding region 222, and the dimensions in the target direction of the gaps, i.e., the spacings, may be 10 μm-20 μm, for example, 10 μm.

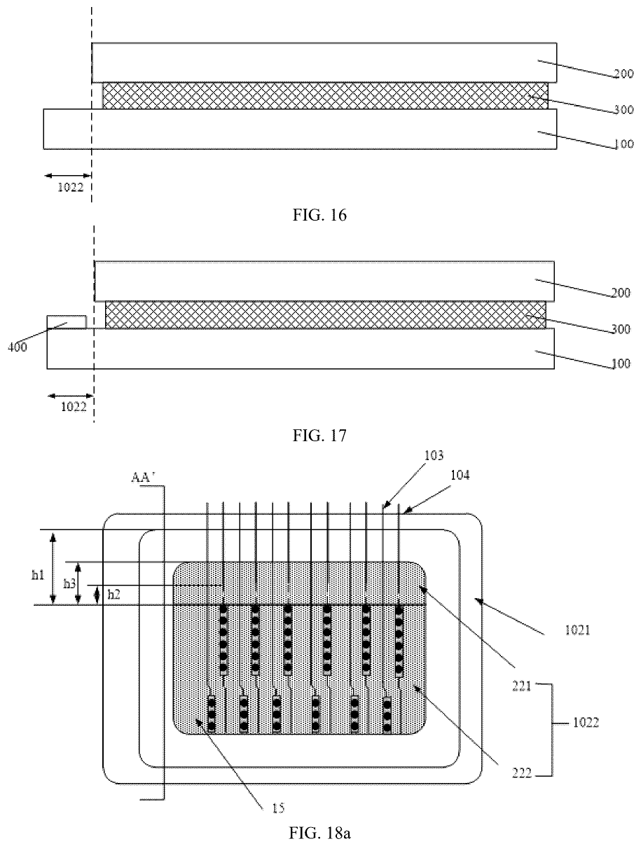

On the basis of the same inventive concept, a display panel is provided. Referring to FIG. 16, FIG. 16 shows a schematic sectional structural diagram of the display panel. As shown in FIG. 16, the display panel may include the array base board 100 according to the above embodiments, and a cell-assembling base board 200 arranged in align with the array base board, wherein a liquid-crystal layer 300 is filled between the cell-assembling base board and the array base board.

In an alternative example, a color-film layer may be disposed on the array base board, so that light filtering can be realized in the path of the incidence from the backlight source to the liquid-crystal layer. In another alternative example, a color-film layer may be disposed on the cell-assembling base board, so that light filtering can be performed to the light exiting from the liquid-crystal layer.

When a color-film layer is disposed on the array base board, the color-film layer may be the organic film layer 132 provided within the displaying region 101 according to the above embodiments; in other words, the organic film layer 132 can implement the function of light filtering. In such a case, all of the film layers disposed within the displaying region 101 may be transparent film layers.

In such an alternative example, for the trenching region 1022 of the array base board, the bonding region 222 and a part of the separating region 221 may be understood as regions of the array base board that grow from the cutting line of the cell-assembling base board. For the separating region 221, the uppermost protecting film layer 13 may be a film layer manufactured by using indium tin oxide ITO, for example, the first thin-film layer 130a. There is a gap between the first thin-film layer 130a and bonding region 222, and, accordingly, one boundary of the orthographic projection of the cell-assembling base board on the array base board may be aligned with the boundary of the first thin-film layer 130a at the side of the bonding region 222. In other words, there is a gap between the orthographic projection of the cell-assembling base board 200 on the array base board 100 and the bonding region 222 of the array base board. In an example, the spacing of the gap is greater than or equal to 10 μm, and less than or equal to 20 μm. In another example, the dimension in the target direction of the gap may be 45 μm-80 μm.

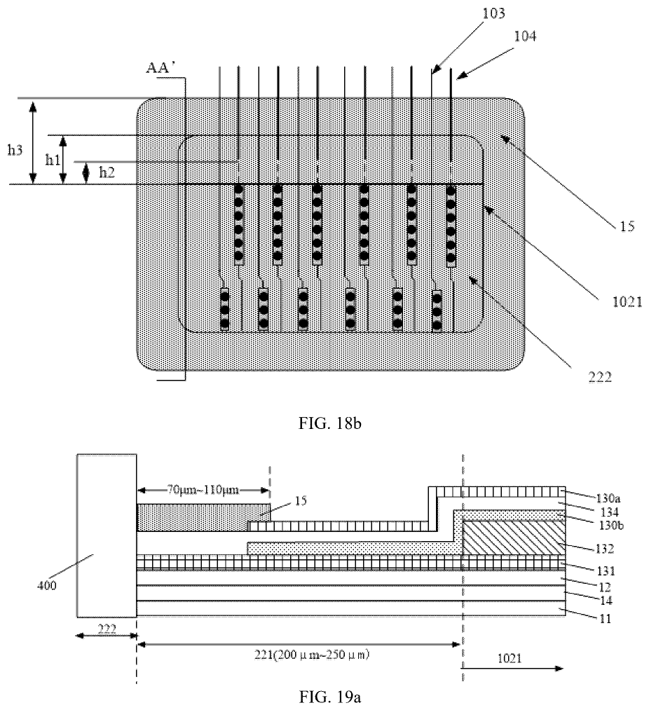

On the basis of the same inventive concept, a display device is provided. Referring to FIGS. 17 and 18, FIG. 17 shows a schematic sectional structural diagram of the display device. As shown in FIG. 17, the display device may include the display panel shown in FIG. 16. The array base board 100 of the display panel includes the bonding region 222, the bonding region 222 includes exported electrodes 2211 lap-joined to the lead-wire layer 12, and the leads of the controlling chip 400 are lap-joined to the exported electrodes 2211.

The controlling chip 400 may be the driving chip, and may also be a touch-controlling chip, which is decided according to whether the display device has the function of touch controlling. When it has the function of touch controlling, then the bonding region may include both of the touch-controlling chip and the driving chip. If not, the bonding region may include the driving chip. Both of the touch-controlling chip and the driving chip are bonded to the lead wires in the lead-wire layer within the bonding region, wherein the touch-controlling chip is specifically bonded to the lead wire connected to the touch-controlling signal line, and the driving chip is specifically bonded to the lead wire connected to the data line.

In some alternative examples of the present embodiment, the array base board of the display device includes the trenching region 1022 and the lead-wire region 1021, and the trenching region 1022 includes the separating region 221 and the bonding region 222. A conducting thin film 15 is laid within the trenching region 1022, and the conducting thin film 15 covers a part or a whole of the protecting film layers 13 extending from the lead-wire region 1021 to the separating region 221.

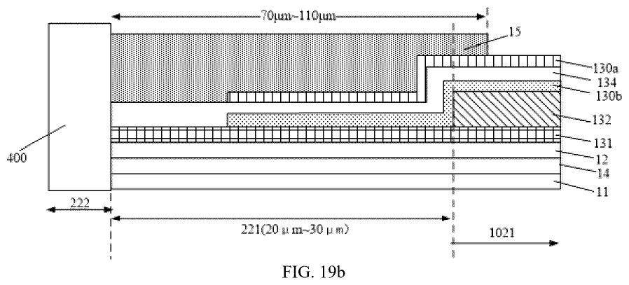

Referring to FIGS. 18a and 18b, taking the array base boardD as an example, FIGS. 18a and 18b show schematic top planar views within the non-displaying region 102 of two types of the display device. Referring to FIGS. 19a and 19b, FIG. 19a is a schematic sectional structural diagram along the direction of AA′ of the display device shown in FIG. 18a. FIG. 19b is a schematic sectional structural diagram along the direction of AA′ of the display device shown in FIG. 18b.

As shown in FIGS. 18a and 19a, in some embodiments, the size of the conducting thin film 15 may be less than the size of the trenching region 1022. Accordingly, the conducting thin film 15 may cover a part of the trenching region 1022, i.e., covering a part of the area of the protecting film layers 13 extending from the lead-wire region 1021 to the separating region 221. Accordingly, the orthographic projection of the conducting thin film 15 on the substrate 11 may be located in the orthographic projection of the trenching region 1022 on the substrate 11; in other words, the orthographic projection of the conducting thin film 15 on the substrate 11 may cover a part of the orthographic projection of the trenching region 1022 on the substrate 11. As an example, the dimension h1 in the target direction of the separating region 221 of the array base board is greater than or equal to 200 μm, and less than or equal to 250 μm. The dimension h3 in the target direction of the conducting thin film 15 may be greater than or equal to 70 μm, and less than or equal to 110 μm. The spacing h2 between the uppermost first thin-film layer 130a within the separating region 221 and the bonding region 222 is 80 μm.

As shown in FIGS. 18b and 19b, in some embodiments, the size of the conducting thin film 15 may be greater than the size of the trenching region 1022. Accordingly, the conducting thin film 15 may cover the whole of the trenching region 1022, i.e., fully covering the protecting film layers 13 extending from the lead-wire region 1021 to the separating region 221. Accordingly, the orthographic projection of the conducting thin film 15 on the substrate 11 may cover the orthographic projection of the trenching region 1022 on the substrate 11. As an example, the dimension h1 in the target direction of the separating region 221 of the array base board of the display device is greater than or equal to 20 μm, and less than or equal to 30 μm. The dimension h3 in the target direction of the conducting thin film 15 is greater than or equal to 70 μm, and less than or equal to 110 μm. The spacing h2 between the uppermost first thin-film layer 130a within the separating region 221 and the bonding region 222 is 10 μm-20 μm.

The embodiments of the description are described in the mode of progression, each of the embodiments emphatically describes the differences from the other embodiments, and the same or similar parts of the embodiments may refer to each other.

Finally, it should also be noted that, in the present text, relation terms such as first and second are merely intended to distinguish one entity or operation from another entity or operation, and that does not necessarily require or imply that those entities or operations have therebetween any such actual relation or order. Furthermore, the terms “include”, “comprise” or any variants thereof are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “including a . . . ” does not exclude additional same element in the process, method, article or device including the element.

The array base board, the display panel and the display device according to the present disclosure have been described in detail above. The principle and the embodiments of the present disclosure are described herein with reference to the particular examples, and the description of the above embodiments is merely intended to facilitate to comprehend the method according to the present disclosure and its core concept. Moreover, for a person skilled in the art, according to the concept of the present disclosure, the particular embodiments and the range of application may be varied. In conclusion, the contents of the description should not be understood as limiting the present disclosure.

A person skilled in the art, after considering the description and implementing the invention disclosed herein, will readily envisage other embodiments of the present disclosure. The present disclosure aims at encompassing any variations, uses or adaptative alternations of the present disclosure, wherein those variations, uses or adaptative alternations follow the general principle of the present disclosure and include common knowledge or common technical means in the art that are not disclosed by the present disclosure. The description and the embodiments are merely deemed as exemplary, and the true scope and spirit of the present disclosure are presented by the following claims.

It should be understood that the present disclosure is not limited to the accurate structure that has been described above and shown in the drawings, and may have various modifications and variations without departing from its scope. The scope of the present disclosure is merely limited by the appended claims.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same embodiment.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “include” does not exclude elements or steps that are not listed in the claims. The word “a” or “an” preceding an element does not exclude the existing of a plurality of such elements. The present disclosure may be implemented by means of hardware including several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. An array base board, comprising a substrate;
the substrate is provided with a displaying region and a non-displaying region, the non-displaying region comprises a lead-wire region and a trenching region, the trenching region is located at one side of the lead-wire region away from the displaying region, the trenching region comprises a bonding region and a separating region, and the separating region is located between the bonding region and the lead-wire region;
both of the lead-wire region and the trenching region comprise a lead-wire layer disposed on the substrate, the lead-wire region further comprises a plurality of types of protecting film layers that are arranged in layer configuration, and the plurality of types of protecting film layers are located at one side of the lead-wire layer away from the substrate; and
at least two types of the protecting film layers within the lead-wire region extend to the separating region, and/or a dimension in a target direction of the separating region is greater than or equal to 20 μm, and less than or equal to 30 μm, wherein the target direction refers to a direction from the bonding region pointing to the lead-wire region.

2. The array base board according to claim 1, wherein the dimension in the target direction of the separating region increases with increasing of a quantity of the protecting film layers extending to the separating region.

3. The array base board according to claim 2, wherein when at least three types of the protecting film layers extend to the separating region, the dimension in the target direction of the separating region is greater than or equal to 200 μm, and less than or equal to 250 μm; and
when two types of the protecting film layers extend to the separating region, the dimension in the target direction of the separating region is greater than or equal to 20 μm, and less than or equal to 30 μm.

4. The array base board according to claim 1, wherein the plurality of types of protecting film layers comprise:
a first passivating layer located at one side of the lead-wire layer away from the substrate;
an organic film layer located at one side of the first passivating layer away from the substrate;
a second passivating layer located at one side of the organic film layer away from the substrate; and
a first thin-film layer located at one side of the second passivating layer away from the substrate; and
the second passivating layer and the first thin-film layer extend to the separating region, the second passivating layer covers the separating region, and there is a gap between the first thin-film layer and the bonding region.

5. The array base board according to claim 4, wherein the first passivating layer further extends to the separating region, and the first passivating layer covers the separating region.

6. The array base board according to claim 4, wherein the dimension in the target direction of the separating region is greater than or equal to 20 μm, and less than or equal to 30 μm.

7. The array base board according to claim 4, wherein a spacing between the bonding region and the first thin-film layer is greater than or equal to 10 μm, and less than or equal to 20 μm.

8. The array base board according to claim 4, wherein the plurality of types of protecting film layers further comprise a second thin-film layer, the second thin-film layer is located at one side of the organic film layer away from the substrate, and the second passivating layer is located at one side of the second thin-film layer away from the substrate;
wherein the second thin-film layer further extends to the separating region, and there is a gap between the second thin-film layer and the bonding region.

9. The array base board according to claim 8, wherein the first passivating layer further extends to the separating region, and the first passivating layer covers the separating region.

10. The array base board according to claim 8, wherein the dimension in the target direction of the separating region is greater than or equal to 20 μm, and less than or equal to 30 μm.

11. The array base board according to claim 10, wherein a spacing between the second thin-film layer and the bonding region is greater than or equal to 10 μm, and less than or equal to 20 μm; and a spacing between the first thin-film layer and the bonding region is greater than or equal to 10 μm, and less than or equal to 20 μm.

12. The array base board according to claim 8, wherein a spacing between the first thin-film layer and the bonding region is less than a spacing between the second thin-film layer and the bonding region.

13. The array base board according to claim 8, wherein the displaying region comprises a plurality of pixel units arranged in an array, and each of the pixel units comprises a pixel electrode, a common electrode and a thin-film transistor;
wherein the pixel electrode is electrically connected to a source-drain electrode of the thin-film transistor, and the common electrode is further from the substrate than the pixel electrode is; and
the first thin-film layer and the common electrode are arranged in a same layer, and the second thin-film layer and the pixel electrode are arranged in a same layer.

14. The array base board according to claim 5, wherein the displaying region comprises a plurality of pixel units arranged in an array, and each of the pixel units comprises a pixel electrode, a common electrode and a thin-film transistor;
wherein the pixel electrode is electrically connected to a source-drain electrode of the thin-film transistor, and the common electrode is closer to the substrate than the pixel electrode is; and
the first thin-film layer and the pixel electrode are arranged in a same layer, and the second thin-film layer and the common electrode are arranged in a same layer.

15. The array base board according to claim 5, wherein a thickness of the first passivating layer is greater than a thickness of the first thin-film layer, and/or a thickness of the second passivating layer is greater than a thickness of the first thin-film layer.

16. A display panel, wherein the display panel comprises the array base board according to claim 1, and a cell-assembling base board arranged in align with the array base board, and a liquid-crystal layer is filled between the cell-assembling base board and the array base board.

17. The display panel according to claim 16, wherein there is a gap between the bonding region of the array base board and an orthographic projection of the cell-assembling base board on the array base board, and a spacing of the gap is greater than or equal to 10 μm, and less than or equal to 20 μm.

18. A display device, wherein the display device comprises a controlling chip, and the display panel according to claims 16;
wherein the array base board of the display panel comprises the bonding region, and the controlling chip is electrically connected to the lead-wire layer within the bonding region.

19. The display device according to claim 18, wherein the array base board of the display device comprises the trenching region and the lead-wire region, and further comprises:
a conducting thin film, wherein an orthographic projection of the conducting thin film on the substrate covers a part or a whole of an orthographic projection of the trenching region on the substrate.

20. The display device according to claim 19, wherein the trenching region comprises the separating region adjacent to the lead-wire region, and the bonding region adjacent to the separating region, and the dimension in the target direction of the separating region is greater than or equal to 20 μm, and less than or equal to 30 μm; and a dimension in the target direction of the conducting thin film is greater than or equal to 70 μm, and less than or equal to 110 μm;
wherein the target direction refers to the direction from the bonding region pointing to the lead-wire region.
